(19) United States
(12) Patent Application Publication
(10) Pub. No.: US 2026/0198326 A1
(43) Pub. Date: Jul. 9, 2026

(54) SEMICONDUCTOR DEVICE AND METHOD OF MANUFACTURING SEMICONDUCTOR DEVICE

(71) Applicant: Taiwan Semiconductor Manufacturing Company, Ltd., Hsinchu (TW)

(72) Inventors: Hong-Shen CHEN, Hsinchu (TW); Hsieh-Hung HSIEH, Hsinchu (TW); Tzu-Jin YEH, Hsinchu (TW)

(73) Assignee: Taiwan Semiconductor Manufacturing Company, Ltd., Hsinchu (TW)

(21) Appl. No.: 19/198,658

(22) Filed: May 5, 2025

Related U.S. Application Data
(60) Provisional application No. 63/741,535, filed on Jan. 3, 2025.

(51) Int. Cl. H01L 23/552; H01L 23/58

(52) U.S. Cl. CPC H10W 42/20; H10W 42/00

(57) ABSTRACT

An embodiment semiconductor device includes a substrate having a first side and a second side opposite the first side; a first set of electronic components at the first side of the substrate; and an isolation structure at the second side of the substrate, and overlapping the first set of electronic components based on a perspective along a vertical direction. The isolation structure includes an array of conductive strips. The isolation structure includes an array of conductive strips, and an open guard ring structure that extends along a periphery of the array of conductive strips and defines a space between two ends of the open guard ring structure. The semiconductor device further includes a passive component or a second set of electronic components at the second side of the substrate.

### PRIORITY CLAIM AND CROSS-REFERENCE

This patent application claims the benefit of U.S. Provisional Patent Application No. 63/741,535 filed on Jan. 3, 2025, the entire disclosure of which is hereby incorporated by reference.

### BACKGROUND

The semiconductor integrated circuit (IC) industry has experienced rapid growth due to continuous improvements in the integration density of a variety of electronic components (e.g., transistors, diodes, resistors, capacitors, inductors, etc.). Technological advances in IC design and material have produced generations of ICs where each generation has smaller and more complex circuits than previous generations. In the course of IC evolution, functional density (i.e., the number of interconnected devices per chip area) has generally increased while geometric size (i.e., the smallest component (or line) that can be fabricated) has decreased.

In some applications, a semiconductor device (e.g., an IC) includes a circuit block that is formed based on electrically connecting electronic components such as one or more active components (e.g., transistors) and/or one or more passive components (e.g., one or more inductors, capacitors, resistors, and/or transmission lines). During operation, a passive component of the circuit block carries a varying current at an operating frequency of the circuit block and therefore causes a magnetic field that penetrates into a substrate of the semiconductor device. In some applications, the magnetic field induces an eddy current within the substrate, which generates its own magnetic field that would lower the quality factor (Q) of a portion of the of the circuit block incorporating the passive component and/or interfere with the operation of the circuit block.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a cross-sectional view of a semiconductor device, in accordance with some embodiments.

FIG. 1B is a simplified cross-sectional view of a portion of the semiconductor device in FIG. 1A, in accordance with some embodiments.

FIG. 2A is a circuit diagram of an inductor-capacitor voltage-controlled oscillator (LC-VCO) example, in accordance with some embodiments.

FIG. 2B is a plan view of a passive component in a semiconductor device implementing the inductors of the LC-VCO in FIG. 2A, in accordance with some embodiments.

FIG. 2C is a plan view of an arrangement of the LC-VCO in FIG. 2A in conjunction with the passive component in FIG. 2B according to a first example without an isolation structure, in accordance with some embodiments.

FIG. 2D is a plan view of an arrangement of the LC-VCO in FIG. 2A in conjunction with the passive component in FIG. 2B according to a second example with an isolation structure, in accordance with some embodiments.

FIGS. 3A-3C are plan views of a first isolation structure example, in accordance with some embodiments.

FIGS. 4A-4C are plan views of a second isolation structure example, in accordance with some embodiments.

FIG. 5 is a graph of phase noises of clock signals in the LC-VCO in FIG. 2A based on absence or presence of an isolation structure as described in FIGS. 2D and 3A-3C, in accordance with some embodiments.

FIG. 6A is a simplified plan view of a configuration including a passive component formed at a back side of a substrate and various port definitions thereof, in accordance with some embodiments.

FIG. 6B is a graph of a coupling factor between two ports as defined in FIG. 6A based on absence or presence of an isolation structure as described in FIGS. 2D and 3A-3C, in accordance with some embodiments.

FIG. 7 is a diagram of a configuration that includes an isolation structure electrically coupled to a filter, in accordance with some embodiments.

FIG. 8 is a simplified cross-sectional view of a portion of a semiconductor device, in accordance with some embodiments.

FIG. 9 is an exploded view of arranging multiple sets of electronic components and one or more isolation structures in a semiconductor device, in accordance with some embodiments.

FIG. 10 is a flowchart of a method of manufacturing a semiconductor device, in accordance with some embodiments.

FIG. 11 is a block diagram of an IC manufacturing system, and an IC manufacturing flow associated therewith, in accordance with some embodiments.

### DETAILED DESCRIPTION

The following disclosure provides many different embodiments, or examples, for implementing different features of the provided subject matter. Specific examples of components and arrangements are described below to simplify this disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, this disclosure may repeat reference numerals and/or letters in the various examples. This repetition is for simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. In addition, the term “made of” may mean either “including” or “consisting of.” In this disclosure, the phrase “one of A, B, and C” means “A, B, and/or C” (A, B, C, A and B, A and C, B and C, or A, B and C), and does not mean one element from A, one element from B, and one element from C, unless otherwise described.

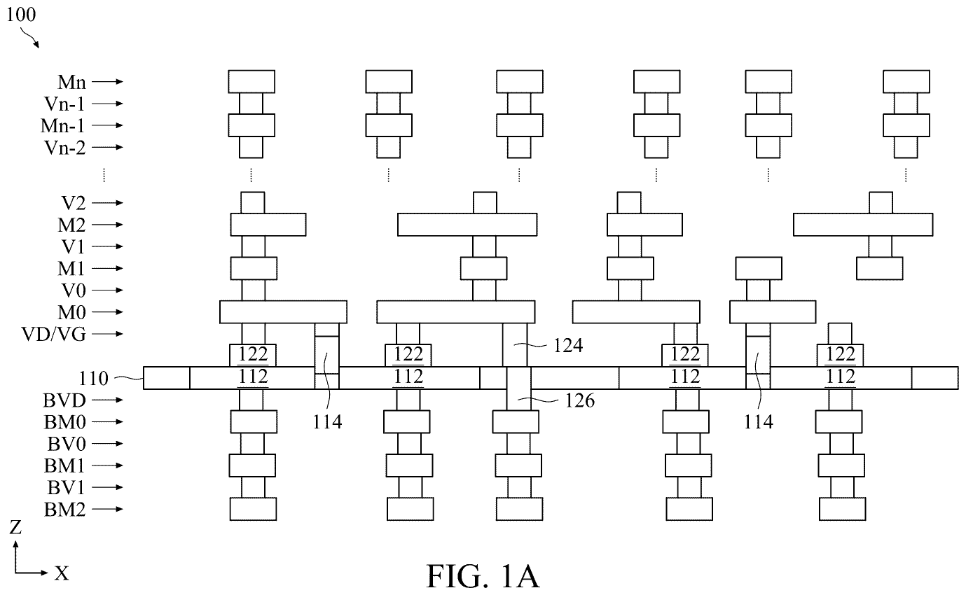

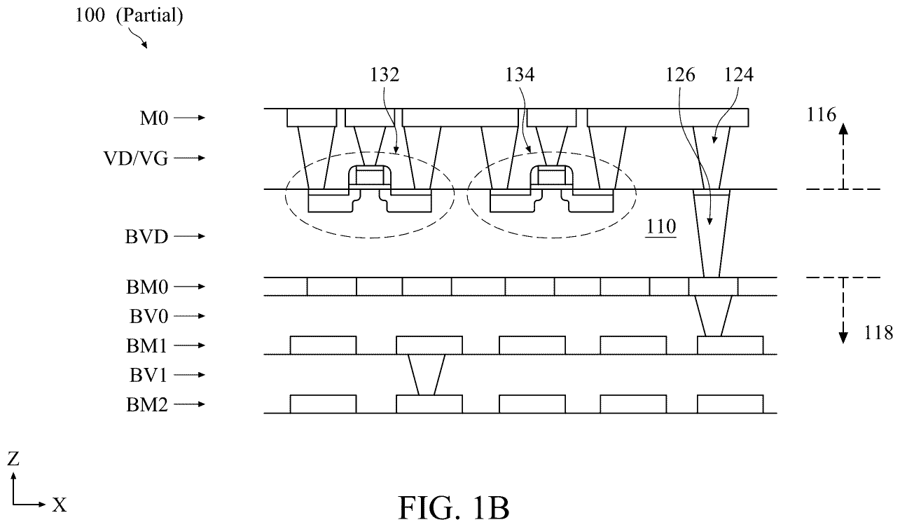

FIG. 1A is a cross-sectional view of a semiconductor device 100, in accordance with some embodiments. In some embodiments, the cross-sectional view is a simplified cross-sectional view, with many features simplified or not depicted.

Semiconductor device 100 in FIG. 1A includes a substrate 110 with active regions 112 and gate structures 114 formed on or partially in substrate 110. In some embodiments, an active region of a transistor corresponds to a doped region, where a channel, drain, and/or source of the transistor are formed based on such doped region. In this example, semiconductor device 100 includes metal-to-drain/source (MD) structures 122 coupled to the active regions 112. In this example, semiconductor device 100 includes via-to-drain/source (VD) structures coupled to MD structures 122 and via-to-gate (VG) structures coupled to gate structures 114 at a VD/VG layer above substrate 110 (with respect to a direction Z). In some embodiments, semiconductor device 100 further includes a plurality of metallization layers (e.g., M0, M1, M2, . . . , Mn−1, and Mn layers) and a plurality of via layers (e.g., V0, V1, V2, . . . , Vn−2, and Vn−1 layers) over the VD/VG layer and substrate 110 (n being a positive integer). In some embodiments, a number of metallization layers over substrate 110 ranges from 8 to 14. In some embodiments, Vn−1 layer denotes the via structures between and connecting conductive lines in Mn−1 layer and Mn layer. In some embodiments, M0 layer denotes the first metallization layer above substrate 110. In some embodiments, the plurality of metallization layers and the plurality of via layers include a conductive material including copper, aluminum, gold, tungsten, a combination thereof, or the like.

Semiconductor device 100 in FIG. 1A, as a non-limiting example, further includes conductive structures disposed under substrate 110. For example, semiconductor device 100 further includes backside metallization layers BM0, BM1, and BM2 and backside via layers BVD, BV0, and BV1. In this example, BVD layer denotes backside via structures between and connecting active regions 112 and backside conductive lines in BM0 layer; BV0 layer denotes backside via structures between and connecting backside conductive lines in BM0 layer and BM1 layer, and BV1 layer denotes backside via structures between and connecting backside conductive lines in BM1 layer and BM2 layer. In some embodiments, BM0 layer denotes the first metallization layer under substrate 110. In this example, semiconductor device 100 includes three backside metallization layers BM0, BM1, and BM2 and corresponding via layers. In some embodiments, a number of backside metallization layers under substrate 110 ranges from 2 to 6. In some embodiments, a portion or all of the backside conductive structures (e.g., backside metallization layers BM0, BM1, and BM2 and backside via layers BVD, BV0, and BV1) are at least partially embedded in substrate 110. In some embodiments, backside metallization layers BM0, BM1, and BM2 and backside via layers BVD, BV0, and BV1 include a conductive material including copper, aluminum, gold, tungsten, a combination thereof, or the like.

In this example, the VD/VG layer further includes a via structure 124 that is on an upper surface of substrate 110 and/or extended into substrate 110 from the upper surface; and the BVD layer further includes a via structure 126 that is on a lower surface of substrate 110 and/or extended into substrate 110 from the lower surface. In this example, via structure 124 and via structure 126 are electrically coupled together. In some embodiments, via structure 126 constitutes a through substrate via that extends through substrate 110.

In some embodiments, semiconductor device 100 includes one or more redistribution layers and conductive pad structures (not in FIG. 1A) over the one or more redistribution layers. In some embodiments, semiconductor device 100 further includes conductive terminal structures (e.g., conductive bumps, copper pillar bumps, solder bumps, or the like, not in FIG. 1A) over the conductive pad structures. In some embodiments, semiconductor device 100 also includes one or more backside redistribution layers and backside conductive pad structures (not in FIG. 1A) under the one or more backside redistribution layers. In some embodiments, semiconductor device 100 also includes backside conductive terminal structures (e.g., conductive bumps, copper pillar bumps, solder bumps, or the like, not in FIG. 1A) under the backside conductive pad structures.

In some embodiments, semiconductor device 100 includes transistors formed based on active regions 112 and gate structures 114 in a front-end-of-line (FEOL) portion of semiconductor device 100. In some embodiments, one or more circuit blocks of semiconductor device 100 are formed based on electrically connecting the transistors in the FEOL portion of semiconductor device 100. In some embodiments, a portion of semiconductor device 100 at and above a given metallization layer (e.g., a M5 layer and above) corresponds to a back-end-of-line (BEOL) portion of semiconductor device 100.

FIG. 1B is a simplified cross-sectional view of a portion (labeled as “100 (Partial)”) of semiconductor device 100 in FIG. 1A, in accordance with some embodiments. Components in FIG. 1B that are the same or similar to those in FIG. 1A are given the same reference labels or reference numbers, and description thereof is thus simplified or omitted. In FIG. 1B, various active regions 112, gate structures 114, and MD structures 122 at an upper side (or front side) 116 of substrate 110 constitute a set of active components, such as transistors 132 and 134. In some embodiments, a circuit block is formed based on electrically connecting the plurality of transistors.

In this example, one or more passive components or power distribution networks to be used in conjunction with the circuit block are formed based on a portion or all of the backside metallization layers BM0, BM1, and BM2 and backside via layers BV0 and BV1. According to one or more embodiments of the present application, in order to implement an isolation structure between the circuit block and the one or more passive components or power distribution networks, the isolation structure is based on a subset of the backside metallization layers and backside via layers (e.g., the backside metallization layer BM0) at a back side 118 of substrate 110; and the one or more passive components or power distribution networks is based on another subset of the backside metallization layers and backside via layers (e.g., the backside metallization layers BM1 and BM2 and the backside via layer BV1) at the back side 118 of substrate 110 farther away from substrate 110 than the isolation structure. In this example, the isolation structure is configured to protect the circuit block (e.g., based on transistors 132 and 134) at the front side 116 of substrate 110 from interference or noise (e.g., electrical fields, magnetic fields, induced eddy current, or the like) caused by the one or more passive components or power distribution networks at the back side 118 of substrate 110.

In some other examples, semiconductor device 100 does not include the one or more passive components or power distribution networks formed based on the backside metallization layers and backside via layers at the back side 118 of substrate 110. Instead, other electronic components (e.g., active components and/or passive components) are present at the backside of substrate 110 as part of semiconductor device 100, or part of another semiconductor device or a circuit board on which semiconductor device 100 is mounted or stacked. In some embodiments, an isolation structure is still formed at the back side 118 of substrate 110 and is configured to protect the circuit block (e.g., based on transistors 132 and 134) at the front side 116 of substrate 110 from interference or noise (e.g., electromagnetic coupling noises via electrical fields, magnetic fields, induced eddy current, or the like) caused by the other electronic components on the back side of substrate 110 and/or on the other semiconductor device or the circuit board on which semiconductor device 100 is mounted or stacked.

According to one or more embodiments of the present application, an isolation structure is formed at the back side 118 of substrate 110 and overlaps the electronic components (e.g., transistors 132 and 134) at the front side 116 of substrate 110 based on a perspective along a vertical direction (e.g., the Z direction). In some embodiments, the isolation structure includes an array of conductive strips. In some embodiments, based on having the isolation structure on the back side of the substrate using a subset of the backside metallization layers and/or the backside via layers, the noise coupling from the back side (either from a passive component or power distribution networks, or from electronic components on another semiconductor device or circuit board) is blocked by the isolation structure. Accordingly, the circuit blocks on the front side of the substrate are less affected by the noise from the back side of the substrate, which corresponds to the resulting semiconductor device having relaxed design margins and/or improved performance. In some embodiments, compared to an isolation structure on the front side of the substrate, forming the isolation structure at the back side of the substrate instead reduces the routing resources at the front side of the substrate and thus improves the routing flexibility at the front side of the substrate.

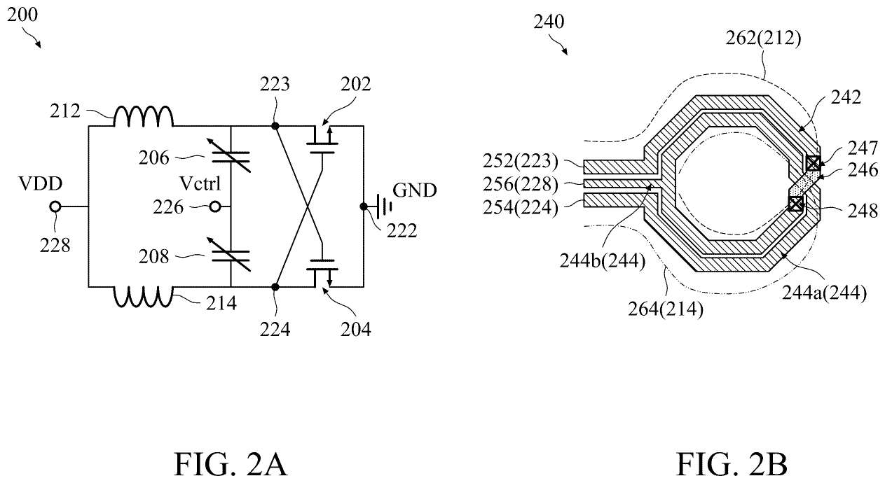

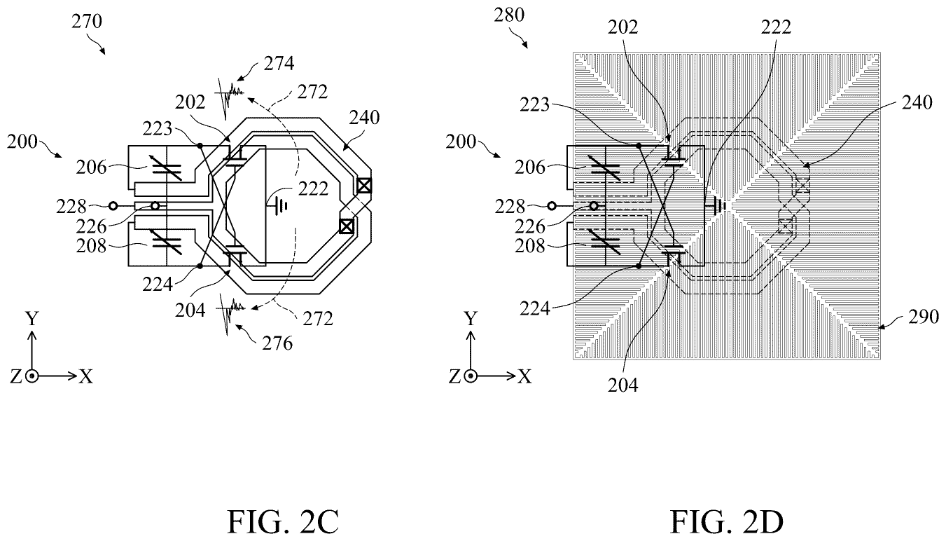

FIG. 2A is a circuit diagram of an inductor-capacitor voltage-controlled oscillator (LC-VCO) 200, in accordance with some embodiments. In FIG. 2A, the circuit diagram includes a non-limiting example of LC-VCO 200. In some embodiments, LC-VCO 200 corresponds to a circuit block in a semiconductor device in which an isolation structure is formed to protect the circuit block from interference or noise (e.g., electromagnetic coupling noises via electrical fields, magnetic fields, induced eddy current, or the like) as discussed with respect to the example of FIG. 1B.

In FIG. 2A, LC-VCO 200 includes a first transistor 202, a second transistor 204, a first variable capacitor 206, a second variable capacitor 208, a first inductor 212, and a second inductor 214. In this non-limiting example, first transistor 202 and second transistor 204 are n-type transistors. In FIG. 2A, a source terminal of first transistor 202 is electrically coupled to a node 222; a drain terminal of first transistor 202 is electrically coupled to a node 223; and a gate terminal of first transistor 202 is electrically coupled to a node 224. Also, a source terminal of second transistor 204 is electrically coupled to node 222; a drain terminal of second transistor 204 is electrically coupled to node 224; and a gate terminal of second transistor 204 is electrically coupled to node 223. In FIG. 2A, first variable capacitor 206 is electrically coupled between node 223 and a node 226; and second variable capacitor 208 is electrically coupled between node 224 and node 226. In this non-limiting example, first inductor 212 is electrically coupled between node 223 and a node 228, and second inductor 214 is electrically coupled between node 224 and node 228. In this non-limiting example, node 222 is configured to carry a ground reference voltage GND; and node 228 is configured to carry a supply voltage VDD. In FIG. 2A, node 226 is configured to receive a control voltage Vctrl for adjusting the capacitance of first variable capacitor 206 and second variable capacitor 208.

FIG. 2B is a plan view of a passive component 240 in a semiconductor device (e.g., corresponding to semiconductor device 100 in FIGS. 1A-1B) implementing inductors 212 and 214 of LC-VCO 200 in FIG. 2A, in accordance with some embodiments. In FIG. 2B, passive component 240 includes a first conductive structure 242 constituting a first outer portion, a second conductive structure 244 constituting a second outer portion 244a and an inner portion 244b, and a third conductive structure 246 electrically coupling the first outer portion (i.e., first conductive structure 242) and the inner portion 244b of second conductive structure 244 through via structures 247 and 248. In some embodiments, first conductive structure 242 and second conductive structure 244 are based on one of the backside metallization layers (e.g., one of backside metallization layers BM1 or BM2) of the semiconductor device, third conductive structure 246 is based on another one of the backside metallization layers (e.g., the other one of backside metallization layers BM1 or BM2) of the semiconductor device, and via structures 247 and 248 are based on one of the backside via layers (e.g., backside via layer BV1) of the semiconductor device.

In FIG. 2B, an end 252 of the first outer portion (e.g., first conductive structure 242) corresponds to node 223 in FIG. 2A; an end 254 of the second outer portion 244a of second conductive structure 246 corresponds to node 224 in FIG. 2A; and an end 256 of the inner portion 244b of second conductive structure 246 corresponds to node 228 in FIG. 2A. in this non-limiting example, a conductive loop 262 defined based on the first outer portion (e.g., first conductive structure 242), third conductive structure 246, via structures 247 and 248, and half of the inner portion 244b corresponds to first inductor 212. Also, in this non-limiting example, a conductive loop 264 defined based on the second outer portion 244a and another half of the inner portion 244b corresponds to second inductor 214.

FIG. 2C is a plan view of an arrangement of LC-VCO 200 in FIG. 2A in conjunction with the passive component 240 in FIG. 2B according to a first example 270 without an isolation structure, in accordance with some embodiments. Components in FIG. 2C that are the same or similar to those in FIGS. 2A and 2B are given the same reference numbers, and description thereof is simplified or omitted. Also, first example 270 corresponds to an implementation example of LC-VCO 200 in a semiconductor device, such as semiconductor device 100 in FIGS. 1A-1B.

In this non-limiting example 270, the semiconductor device includes a substrate (e.g., substrate 110) having a first side (e.g., front side 116 in FIG. 1B) and a second side (e.g., back side 118 in FIG. 1B) opposite the first side. In FIG. 2C, inductors 212 and 214 of LC-VCO 200 that are formed at the back side of the semiconductor device are presented based on the plan view of passive component 240 in FIG. 2B. In FIG. 2C, a set of electronic components of LC-VCO 200 that are formed at the front side of the semiconductor device, such as first transistor 202, second transistor 204, first variable capacitor 206, and second variable capacitor 208, are presented based on the corresponding circuit diagram component symbols in order to more clearly indicate the spatial relationship between the electronic components of LC-VCO 200 that are formed at the front side of the semiconductor device and the components (e.g., inductors 212 and 214) of LC-VCO 200 that are formed at the back side of the semiconductor device.

In FIG. 2C, the current in passive component 240 during operation of LC-VCO 200 causes noise coupling (indicated by the arrows with reference number 272) to the set of electronic components of LC-VCO 200 at the front side of the semiconductor device. For example, the noise coupling 272 causes noise 274 at first transistor 202 and causes noise 276 at second transistor 204. In some embodiments, the noises 274 and 276 interfere with the operations of first transistor 202 and second transistor 204 and degrade the operations of LC-VCO 200 in the form of, for example, increased phase noise of the clock signals at node 223 and node 224.

FIG. 2D is a plan view of an arrangement of LC-VCO 200 in FIG. 2A in conjunction with the passive component 240 in FIG. 2B according to a second example 280 with an isolation structure 290, in accordance with some embodiments. Components in FIG. 2D that are the same or similar to those in FIGS. 2A-2C are given the same reference numbers, and description thereof is simplified or omitted. Also, second example 280 corresponds to an implementation example of LC-VCO 200 in a semiconductor device, such as semiconductor device 100 in FIGS. 1A-1B.

Compared to example 270, example 280 in FIG. 2D further includes an isolation structure 290 at the back side of the substrate, and overlapping the set of electronic components (e.g., first transistor 202, second transistor 204, first variable capacitor 206, and second variable capacitor 208) at the front side of the substrate based on a perspective along a vertical direction (e.g., the Z direction in FIG. 1B or the direction vertically passing through the drawing sheet in FIG. 2D). In some embodiments, passive component 240 is based on one or more conductive structures at the second side of the substrate (e.g., backside metallization layers BM1 or BM2 and backside via layer BV1). In some embodiments, isolation structure 290 is based on a backside metallization layer closer to the substrate than passive component 240 (e.g., backside metallization layer BM0), such that isolation structure 290 is between the substrate and passive component 240.

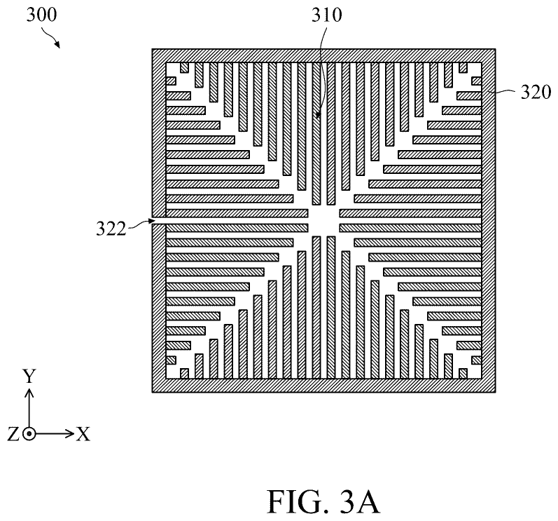

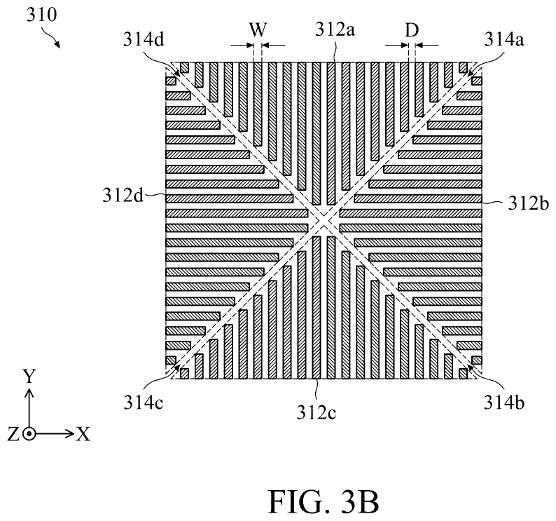

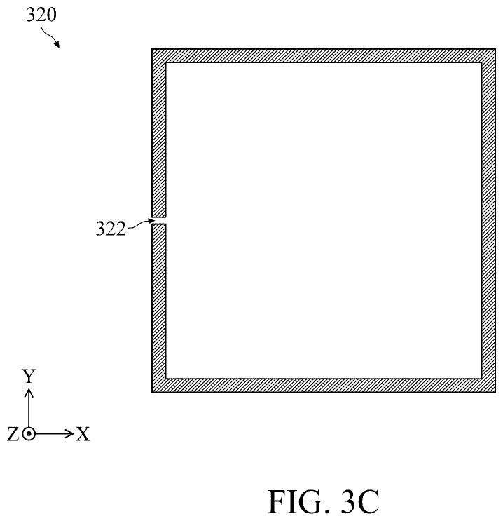

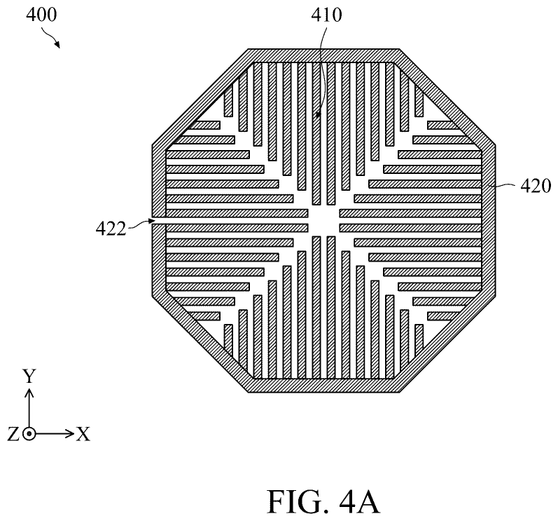

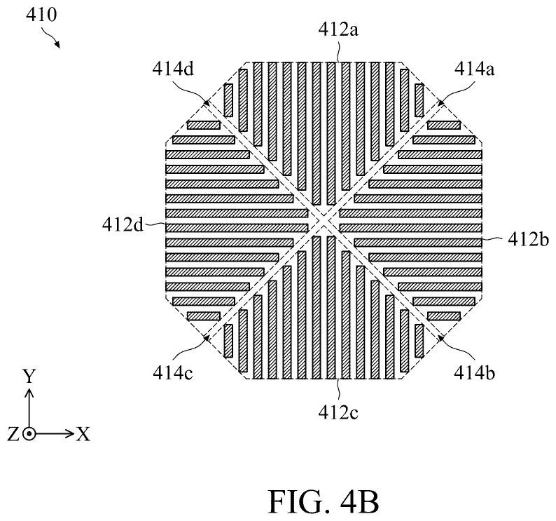

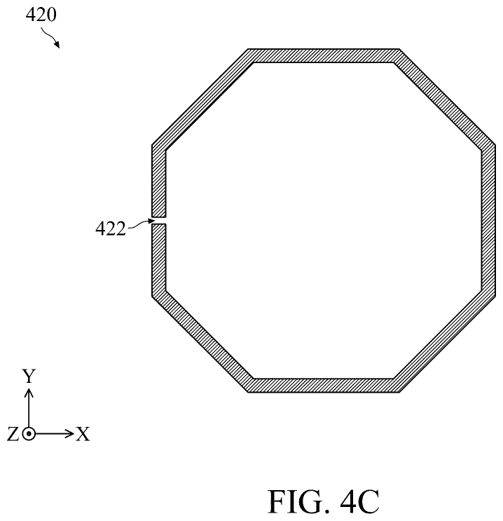

In this example, isolation structure 290 includes an array of conductive strips. In this example, isolation structure 290 further includes an open guard ring structure that extends along a periphery of the array of conductive strips and defines a space between two ends of the open guard ring structure. In some embodiments, isolation structure 290 is electrically coupled to a ground reference voltage. In some embodiments, the pattern of isolation structure 290 is designed to avoid a close-loop formation in order to avoid or reduce the scale of induced current in the substrate. Accordingly, the noise in example 280 corresponding to noise coupling 272 in example 270 is avoided or reduced by the implementation of isolation structure 290. The configuration of isolation structure 290 will be further described based on the examples in FIGS. 3A-4C.

FIG. 3A is a plan view of a first isolation structure example 300, in accordance with some embodiments. In some embodiments, isolation structure 300 is usable as an isolation structure at a back side of a semiconductor device, such as isolation structure 290 in FIG. 2D. In some embodiments, isolation structure 300 is formed based on a backside metallization layer of the semiconductor device. In some embodiments, isolation structure 300 is formed based on a backside metallization layer of the semiconductor device that is closest to the substrate of the semiconductor device among all the backside metallization layer(s) thereof. In some embodiments, isolation structure 300 includes a conductive material including copper, aluminum, gold, or the like, or a combination thereof. In some embodiments, one or more conductive structures are at the back side of the substrate, and isolation structure 300 is between the substrate and the one or more conductive structures. In some embodiments, the one or more conductive structures are configured as an inductor (e.g., passive component 240 in FIG. 2B), a capacitor, a power distribution network, or the like.

In FIG. 3A, isolation structure 300 includes an array of conductive strips 310 and an open guard ring structure 320 that extends along a periphery of the array of conductive strips 310. In this non-limiting example, open guard ring structure 320 defines a space 322 between two ends of the open guard ring structure. The conductive strips 310 extend from the periphery of the array toward an inner side of open guard ring structure 320. The details of conductive strips 310 and open guard ring structure 320 of first isolation structure example 300 are described separately based on the partial plan views in FIGS. 3B and 3C. In FIGS. 3A-3C, to more clearly describe isolation structure 300, the size of various features of isolation structure 300 is not depicted to scale.

In FIG. 3B, the array of conductive strips 310 includes a plurality of conductive strip groups 312a, 312b, 312c, and 312d separated by corresponding gaps 314a, 314b, 314c, and 314d. In some embodiments, the plurality of conductive strip groups includes at least a first conductive strip group having corresponding conductive strips extending along a first direction and a second conductive strip group having corresponding conductive strips extending along a second direction different from the first direction. For example, in FIG. 3B, a first conductive strip group 312a has corresponding conductive strips extending along a first direction (e.g., the Y direction), a second conductive strip group 312b has corresponding conductive strips extending along a second direction (e.g., the X direction), a third conductive strip group 312c has corresponding conductive strips extending along the first direction (e.g., the Y direction), and a fourth conductive strip group 312d has corresponding conductive strips extending along the second direction (e.g., the X direction). In this example, the first direction (e.g., the Y direction) and the second direction (e.g., the X direction) are orthogonal to each other.

In some embodiments, a width W of each conductive strip of the array of conductive strips 310 is less than a signal wavelength at an operating frequency of the set of electronic components forming a circuit block at the front side of the substrate. In some embodiments, width W is less than 1/10 of the signal wavelength at the operating frequency of the set of electronic components. In some embodiments, a distance D between adjacent conductive strips of the array of conductive strips 310 is less than the signal wavelength at the operating frequency of the set of electronic components. In some embodiments, distance D is less than 1/10 of the signal wavelength at the operating frequency of the set of electronic components. In some embodiments, a smaller width W corresponds to a smaller parasitic capacitance, which would have less negative impacts on the circuit performance. Of course, the width W and the distance D of the array of conductive strips 310 are set to comply with a set of design rules of the backside metallization layer in which the isolation structure 300 is formed. In some embodiments, width W and distance D are less than 1/10 of the signal wavelength, and are greater than the corresponding minimum width and minimum spacing according to the set of design rules.

Moreover, in FIG. 3C, open guard ring structure 320 defines space 322 between two ends of the open guard ring structure. In some embodiments, space 322 is arranged at a side adjacent to where the ends 252, 254, and 256 of passive component 240 (as illustrated in the examples in FIGS. 2B and 2D) are located. In some embodiments, the periphery of the array of conductive strips 310 is based on a polygon, including a square, a rectangle, a hexagon, or an octagon. In this example, the periphery of the array of conductive strips 310 corresponds to a square, and open guard ring structure 320 extends along the sides of the square.

FIG. 4A is a plan view of a second isolation structure example 400, in accordance with some embodiments. In some embodiments, isolation structure 400 is usable as an isolation structure at a back side of a semiconductor device, such as isolation structure 290 in FIG. 2D. In some embodiments, isolation structure 400 is a variation of isolation structure 300 and is formed based on a backside metallization layer of the semiconductor device. In FIG. 4A, isolation structure 400 includes an array of conductive strips 410 and an open guard ring structure 420 that extends along a periphery of the array of conductive strips 410. In this non-limiting example, open guard ring structure 420 defines a space 422 between two ends of the open guard ring structure.

The conductive strips 410 extend from the periphery of the array toward an inner side of open guard ring structure 420. The details of conductive strips 410 and open guard ring structure 420 of second isolation structure example 400 are described separately based on the partial plan views in FIGS. 4B and 4C. In FIGS. 4A-4C, to more clearly describe isolation structure 400, the size of various features of isolation structure 400 is not depicted to scale.

In FIG. 4B, the array of conductive strips 410 includes a plurality of conductive strip groups 412a, 412b, 412c, and 412d separated by corresponding gaps 414a, 414b, 414c, and 414d. In some embodiments, the array of conductive strips 410 is based on a width and spacing configuration similar to that of the array of conductive strips 310 in FIG. 3B. Compared to the array of conductive strips 310 in FIG. 3B, the array of conductive strips 410 has a periphery based on the shape of an octagon. In FIG. 4B, as a non-limiting example, array of conductive strips 410 includes a first conductive strip group 412a having corresponding conductive strips extending along a first direction (e.g., the Y direction), a second conductive strip group 412b having corresponding conductive strips extending along a second direction (e.g., the X direction), a third conductive strip group 412c having corresponding conductive strips extending along the first direction (e.g., the Y direction), and a fourth conductive strip group 412d having corresponding conductive strips extending along the second direction (e.g., the X direction).

Moreover, in FIG. 4C, open guard ring structure 420 defines space 422 between two ends of the open guard ring structure. In some embodiments, space 422 is arranged at a side adjacent to where the ends 252, 254, and 256 of passive component 240 (as illustrated in the examples in FIGS. 2B and 2D) locate. In this non-limiting example, the periphery of the array of conductive strips 410 is based on the shape of an octagon, and open guard ring structure 420 extends along the sides of the octagon.

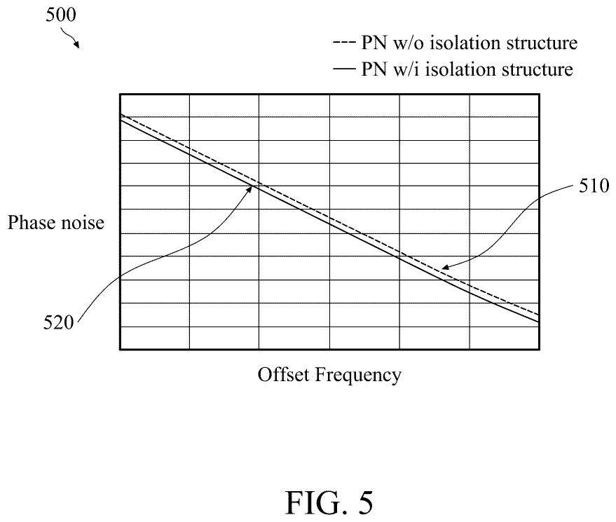

FIG. 5 is a graph 500 of phase noise of clock signals at node 223 or node 224 in LC-VCO 200 in FIG. 2A based on absence or presence of an isolation structure as described in FIGS. 2D and 3A-3C, in accordance with some embodiments. As illustrated above, the LC-VCO includes inductors at the back side of a substrate, and other electronic components at the front side of the substrate. Also, the isolation structure (if included) is at the back side of the substrate between the inductors and the substrate.

In graph 500, the horizontal axis represents the frequency offset from a carrier frequency (in the units of Hertz (Hz) according to a logarithmic scale ranging from 100 Hz to 100 MHz), and the vertical axis represents the phase noise generated by the LC-VCO (in the units of decibels below the carrier per Hertz (dBc/Hz) ranging from −160 dBc/Hz to 60 dBc/Hz). In graph 500, curve 510 indicates the phase noise performance of the LC-VCO implemented without inclusion of an isolation structure based on one or more embodiments of this disclosure. Also, curve 520 indicates the phase noise performance of the LC-VCO implemented with inclusion of an isolation structure based on one or more embodiments of this disclosure. In FIG. 5, curves 510 and 520 indicate that the presence of the isolation structure at the back side of a substrate based on one or more embodiments of this disclosure improves the phase noise performance of the LC-VCO.

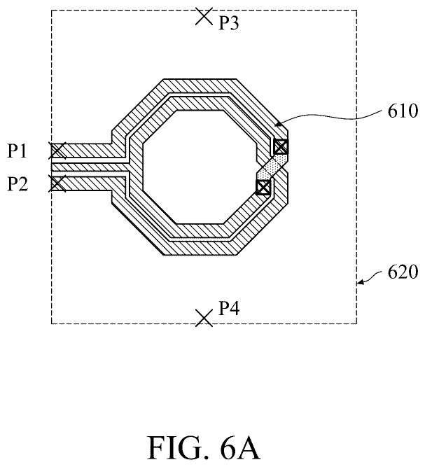

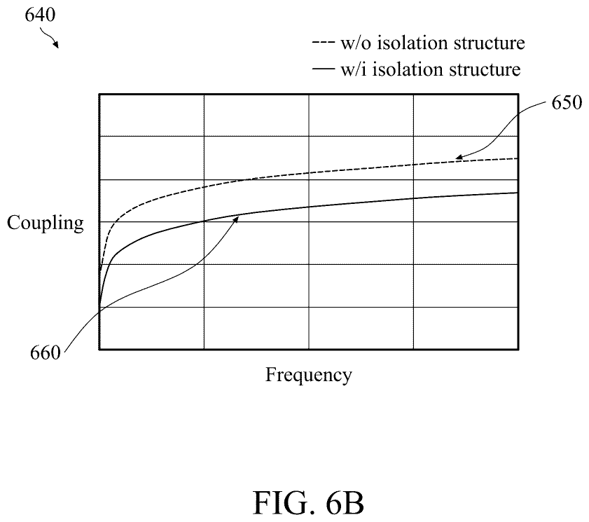

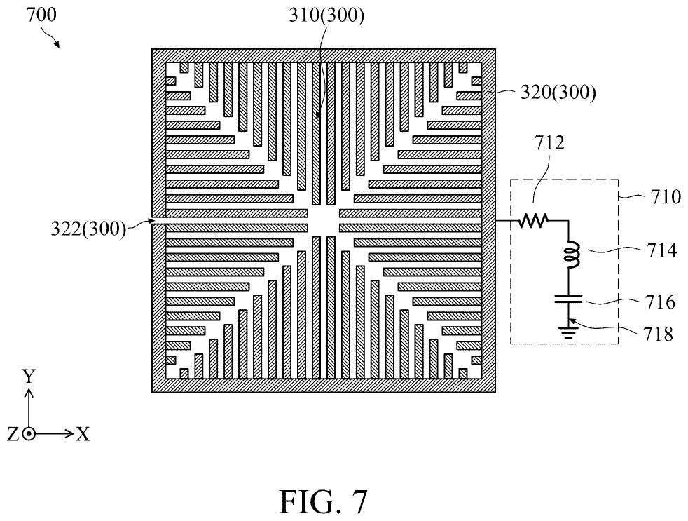

FIG. 6A is a simplified plan view of a configuration including a passive component 610 formed at a back side of a substrate and various port definitions thereof, in accordance with some embodiments. In some embodiments, passive component 610 corresponds to passive component 240 in FIGS. 2C and 2D. FIG. 6A also includes a dashed-line box 620 indicating a position of an isolation structure at the back side of the substrate based on one or more embodiments of this disclosure, in a case where an isolation structure as described in this disclosure is included in the resulting semiconductor device. Moreover, FIG. 6A includes ports P1 and P2 corresponding to two ends of passive component 610 at the back side of the substrate; port P3 corresponding to a position on the front side of the substrate, and port P4 corresponding to a position on the front side of the substrate.

FIG. 6B is a graph 640 of a coupling factor between port P3 and port P1 in FIG. 6A based on the absence or presence of an isolation structure as described in FIGS. 2D and 3A-3C, in accordance with some embodiments. In graph 640, the horizontal axis represents the frequency of an input signal (in the units of Hertz (Hz) according to a logarithmic scale ranging from 0 Hz to 40 GHz) applied to port P1, and the vertical axis represents the coupling factor based on a ratio of a detected signal level at port P3 versus the input signal (in the units of decibels (dB) ranging from −120 dB to 0 dB). In graph 640, curve 650 indicates the coupling factor that is measured without inclusion of an isolation structure based on one or more embodiments of this disclosure. Also, curve 660 indicates the coupling factor that is measured with inclusion of an isolation structure based on one or more embodiments of this disclosure. In FIG. 6B, curves 650 and 660 indicate that the presence of the isolation structure at the back side of a substrate based on one or more embodiments of this disclosure lowers the coupling factor between port P3 and port P1. In some embodiments, the presence of the isolation structure at the back side of a substrate based on one or more embodiments of this disclosure would similarly lower the coupling factors between port P3 and port P2, between port P4 and port P1, and between port P4 and port P2.

FIG. 7 is a diagram of a configuration 700 that includes an isolation structure (e.g., isolation structure 300 as a non-limiting example) electrically coupled to a filter 710, in accordance with some embodiments. Components in FIG. 7 that are the same or similar to those in FIG. 3A are given the same reference numbers, and the description thereof is thus simplified or omitted. Also, while configuration 700 is illustrated as based on isolation structure 300, the modifications described with respect to configuration 700 are also applicable to one or more other isolation structure examples described in this disclosure.

In FIG. 7, configuration 700 includes isolation structure 300, which includes an array of conductive strips 310 and an open guard ring structure 320 that extends along a periphery of the array of conductive strips 310 with a space 322 between two ends of the open guard ring structure. In this non-limiting example, configuration 700 further includes a filter 710 (e.g., a notch filter or a band-stop filter) electrically coupled to isolation structure 300 and configured to reduce a signal component within a band-stop frequency band based on an operating frequency of a set of electronic components of a circuit block to be protected by isolation structure 300 (e.g., first transistor 202, second transistor 204, first variable capacitor 206, and second variable capacitor 208 of LC-VCO 200 in FIG. 2D). In some embodiments, the set of electronic components and the filter 710 are formed at the front side of a substrate, and isolation structure 300 is formed at the back side of the substrate.

In this non-limiting example, filter 710 includes a resistor 712, an inductor 714, and a capacitor 716 electrically connected in series between isolation structure 300 and a node 718 configured to carry a ground reference voltage. In some embodiments, the operating frequency of the set of electronic components ranges from 1 megahertz (MHz) to 100 gigahertz (GHz). In some embodiments, capacitor 716 has a capacitance on the order of tens of nanofarad (nF), and inductor 714 has an inductance on the order of tens of nanohenry (nH).

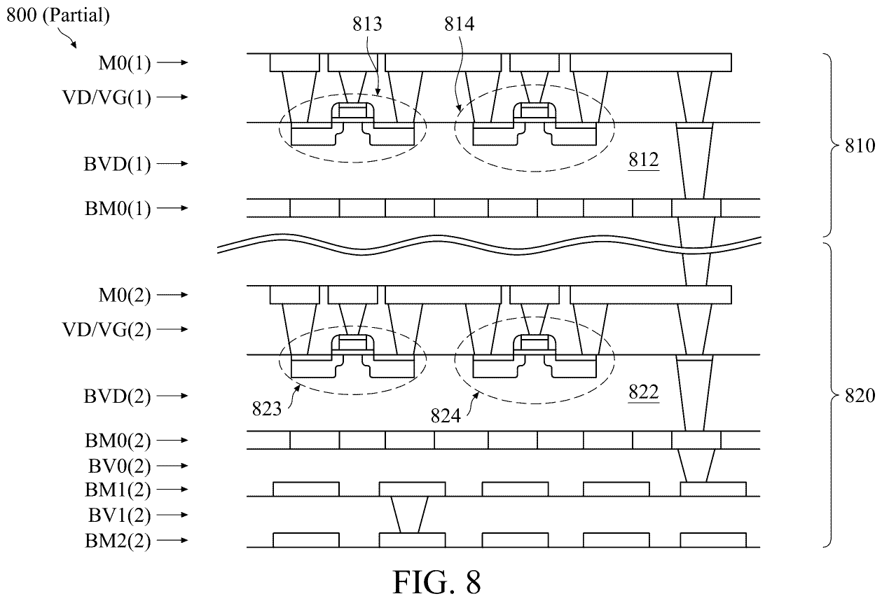

FIG. 8 is a simplified cross-sectional view of a portion of a semiconductor device 800, in accordance with some embodiments. In FIG. 8, semiconductor device 800 includes a first semiconductor die 810 and a second semiconductor die 820 attached to first semiconductor die 810.

First semiconductor die 810 includes a substrate 812, active components (e.g., transistors 813 and 814) formed at a front side of substrate 812, various metallization layers and via layers (e.g., metallization layer labeled as “M0(1)” and a VD/VG layer labeled as “VD/VG layer(1)”) at the front side of substrate 812, and various backside metallization layers and backside via layers (e.g., backside metallization layer BM0(1) and backside via layer BVD (1)) at the back side of substrate 812. Also, second semiconductor die 820 includes a substrate 822, active components (e.g., transistors 823 and 824) formed at a front side of substrate 822, various metallization layers and via layers (e.g., metallization layer labeled as “M0(2)” and a VD/VG layer labeled as “VD/VG layer(2)”) at the front side of substrate 822, and various backside metallization layers and backside via layers (e.g., backside metallization layers BM0(2), BM1(2), and BM2(2) and backside via layers BVD(2), BV0(2), and BV1(2)) at the back side of substrate 812.

In some embodiments, a first set of electronic components of a circuit block is formed at the front side of substrate 812 of first semiconductor die 810. In some embodiments, a second set of electronic components of the circuit block or another circuit block is formed at the front side of substrate 822 of second semiconductor die 820. In some embodiments, one or more passive components or power distribution networks are formed at the backside of substrate 822 of second semiconductor die 820 (e.g., based on backside metallization layers BM1(2) and BM2(2) and backside via layer BV1(2)).

In this non-limiting example, a first isolation structure is formed at the back side of substrate 812 (e.g., based on backside metallization layer BM0(1)), and overlapping the first set of electronic components at the front side of substrate 812 of first semiconductor die 810 in a manner similar to the example in FIG. 2D. Also, in this non-limiting example, a second isolation structure is formed at the back side of substrate 822 (e.g., based on backside metallization layer BM0(2)), and overlapping the second set of electronic components at the front side of substrate 822 of second semiconductor die 820 in a manner similar to the example in FIG. 2D. In some embodiments, the isolation structure at the back side of substrate 812 is configured to protect the first set of electronic components at the front side of substrate 812 from at least interference or noise (e.g., electromagnetic coupling noises via electrical fields, magnetic fields, induced eddy current, or the like) caused by the second set of electronic components at the front side of substrate 822. In some embodiments, the isolation structure at the back side of substrate 822 is configured to protect the second set of electronic components at the front side of substrate 822 from at least interference or noise (e.g., electromagnetic coupling noises via electrical fields, magnetic fields, induced eddy current, or the like) caused by the one or more passive components or power distribution networks at the backside of substrate 822.

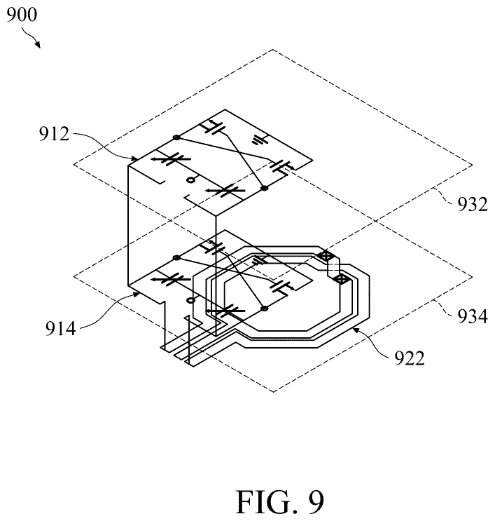

FIG. 9 is an exploded view of arranging multiple sets of electronic components and one or more isolation structures in a semiconductor device 900, in accordance with some embodiments. FIG. 9 is a simplified exploded view emphasizing the spatial relationship among various sets of electronic components and isolation structure thereof, and certain details are simplified or omitted.

In FIG. 9, semiconductor device 900 includes a first set of electronic components 912 at a front side of a substrate of a first semiconductor die and a second set of electronic components 914 at a front side of a substrate of a second semiconductor die. In this example, first set of electronic components 912 and second set of electronic components 914 correspond to a same circuit block or two different circuit blocks. Moreover, semiconductor device 900 includes a passive component 922 at a backside of a substrate of the second semiconductor die. In this example, passive component 922 includes an inductive device. In some embodiments, passive component 922 includes an inductor, a capacitor, or a power distribution network.

Moreover, in view of the example in FIG. 8, semiconductor device 900 includes a first isolation structure 932 at a back side of the substrate of the first semiconductor die, and a second isolation structure 934 at the back side of the substrate of the second semiconductor die. In this example, second isolation structure 934 is between passive component 922 and the substrate of the second semiconductor die.

In this non-limiting example, the first isolation structure 932 is configured to protect the first set of electronic components 912 at the front side of the substrate of the first semiconductor die from at least interference or noise (e.g., electromagnetic coupling noises via electrical fields, magnetic fields, induced eddy current, or the like) caused by the second set of electronic components 914 at the front side of the substrate of the second semiconductor die. In this non-limiting example, the second isolation structure 934 is configured to protect the second set of electronic components 914 at the front side of the substrate of the second semiconductor die from at least interference or noise (e.g., electromagnetic coupling noises via electrical fields, magnetic fields, induced eddy current, or the like) caused by the passive component 922 at the back side of the substrate of the second semiconductor die.

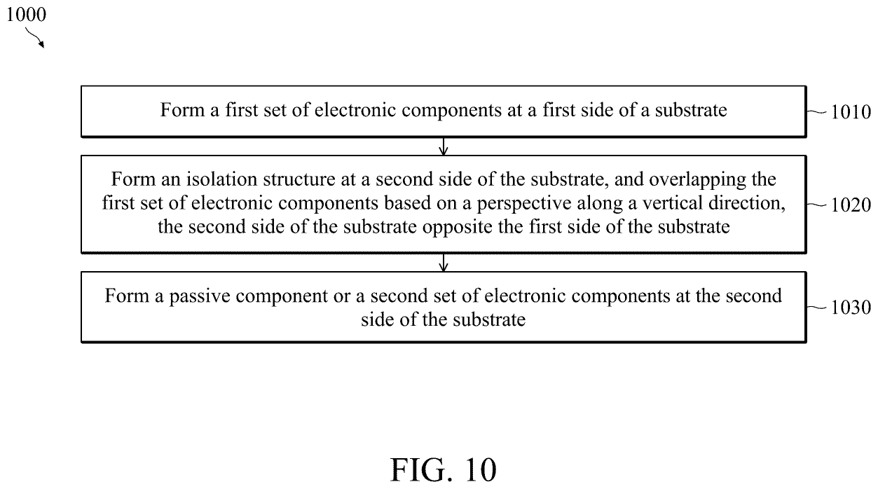

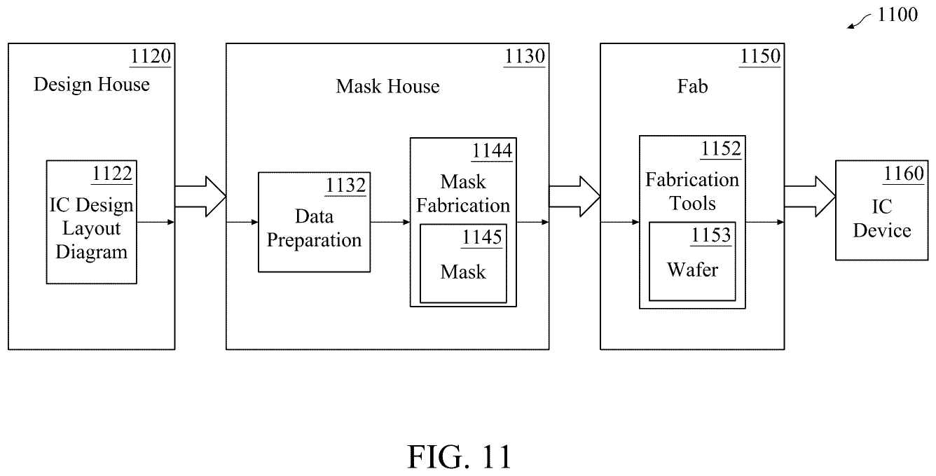

FIG. 10 is a flowchart of a method 1000 of manufacturing a semiconductor device, in accordance with some embodiments. In some embodiments, the semiconductor device manufactured based on method 1000 corresponds to the examples in FIGS. 1B, 2D, and 8-9B in view of the isolation structure examples in FIGS. 3A-4C and 7. In some embodiments, method 1000 is usable in conjunction with an IC manufacturing system as discussed with respect to the IC manufacturing system 1100 in FIG. 11. Method 1000 includes blocks 1010-1030.

At block 1010, a first set of electronic components (e.g., first transistor 202, second transistor 204, first variable capacitor 206, and second variable capacitor 208 in FIG. 2D or first set of electronic components 912 in FIG. 9) is formed at a first side (e.g., a front side) of a substrate (e.g., substrate 110 in FIG. 1B or substrate 812 in FIG. 8).

At block 1020, an isolation structure (e.g., isolation structure 290 in FIG. 2D, isolation structure 300 in FIG. 3A, isolation structure 400 in FIG. 4A, or first isolation structure 932 in FIG. 9) is formed at a second side (e.g., back side) of the substrate, and overlapping the first set of electronic components based on a perspective along a vertical direction. In some embodiments, the second side of the substrate is opposite the first side of the substrate. In some embodiments, the isolation structure includes an array of conductive strips (e.g., array of conductive strips 310 in FIG. 3A or array of conductive strips 410 in FIG. 4A). In some embodiments, the isolation structure further includes an open guard ring structure (e.g., open guard ring structure 320 in FIGS. 3A and 3C or open guard ring structure 420 in FIGS. 4A and 4C) that extends along a periphery of the array of conductive strips and defines a space (e.g., space 322 in FIGS. 3A and 3C or space 422 in FIGS. 4A and 4C) between two ends of the open guard ring structure.

In some embodiments, a width of each conductive strip of the array of conductive strips is less than 1/10 of a signal wavelength at an operating frequency of the set of electronic components. In some embodiments, a distance between adjacent conductive strips of the array of conductive strips is less than 1/10 of the signal wavelength at the operating frequency of the set of electronic components. In some embodiments, the isolation structure includes a conductive material including copper, aluminum, gold, or a combination thereof.

In some embodiments, the forming the isolation structure at block 1020 further includes configuring the periphery of the array of conductive strips based on a polygon, including a square, a rectangle, a hexagon, or an octagon. In some embodiments, the forming the isolation structure at block 1020 further includes configuring the array of conductive strips as including a plurality of conductive strip groups separated by corresponding gaps, as illustrated with respect to the examples in FIGS. 3B and 4B. In some embodiments, the plurality of conductive strip groups includes a first conductive strip group (e.g., conductive strip group 312a in FIG. 3B or conductive strip group 412a in FIG. 4B) having corresponding conductive strips extending along a first direction (e.g., the Y direction in FIG. 3B or FIG. 4B), a second conductive strip group (e.g., conductive strip group 312b in FIG. 3B or conductive strip group 412b in FIG. 4B) having corresponding conductive strips extending along a second direction (e.g., the X direction in FIG. 3B or FIG. 4B), a third conductive strip group (e.g., conductive strip group 312c in FIG. 3B or conductive strip group 412c in FIG. 4B) having corresponding conductive strips extending along the first direction, and a fourth conductive strip group (e.g., conductive strip group 312d in FIG. 3B or conductive strip group 412d in FIG. 4B) having corresponding conductive strips extending along the second direction. In some embodiments, the first direction and the second direction are orthogonal to each other.

At block 1030, a passive component (e.g., passive component 240 in FIG. 2B or passive component 922 in FIG. 9) or a second set of electronic components (e.g., transistors 823 and 824 in FIG. 8 or the second set of electronic components 914 in FIG. 9) is formed at the second side of the substrate. In some embodiments, based on the passive component being at the second side of the substrate, the isolation structure is between the substrate and the passive component, and the passive component includes an inductor, a capacitor, or a power distribution network (e.g., passive component 240 in FIG. 2D). In some embodiments, based on the second set of electronic components being at the second side of the substrate, the isolation structure is between the substrate and the second set of electronic components.

In some embodiments, the forming the passive component at the second side of the substrate includes disposing one or more conductive structures at the second side of the substrate, where the isolation structure is between the substrate and the one or more conductive structures, and the passive component is based on the one or more conductive structures. In some embodiments, the forming the second set of electronic components at the second side of the substrate includes including the second set of electronic components in a first semiconductor die that includes the first set of electronic components, the substrate, and the isolation structure. In some embodiments, the forming the second set of electronic components at the second side of the substrate includes including the second set of electronic components in a second semiconductor die and attaching the second semiconductor die to the first semiconductor die.

FIG. 11 is a block diagram of an IC manufacturing system 1100, and an IC manufacturing flow associated therewith, in accordance with some embodiments. In some embodiments, based on a layout diagram, at least one of (A) one or more semiconductor masks or (B) at least one component in a layer of a semiconductor integrated circuit is fabricated using manufacturing system 1100.

In FIG. 11, IC manufacturing system 1100 includes entities, such as a design house 1120, a mask house 1130, and an IC manufacturer/fabricator (fab) 1150, that interact with one another in the design, development, and manufacturing cycles and/or services related to manufacturing an IC device 1160. The entities in system 1100 are connected by a communications network. In some embodiments, the communications network is a single network. In some embodiments, the communications network is a variety of different networks, such as an intranet and the Internet. The communications network includes wired and/or wireless communication channels. Each entity interacts with one or more of the other entities and provides services to and/or receives services from one or more of the other entities. In some embodiments, two or more of design house 1120, mask house 1130, and IC fab 1150 is owned by a single larger company. In some embodiments, two or more of design house 1120, mask house 1130, and IC fab 1150 coexist in a common facility and use common resources.

Design house (or design team) 1120 generates an IC design layout diagram 1122 (e.g., a layout plan). IC design layout diagram 1122 includes various geometrical patterns designed for an IC device 1160. The geometrical patterns correspond to patterns of metal, oxide, or semiconductor layers that make up the various components of IC device 1160 to be fabricated. The various layers combine to form various IC features. For example, a portion of IC design layout diagram 1122 includes various IC features, such as an active region, gate electrode, source and drain, metal lines or vias of an interlayer interconnection, and openings for bonding pads, to be formed in a semiconductor substrate (such as a silicon wafer) and various material layers disposed on the semiconductor substrate. Design house 1120 implements a proper design procedure to form IC design layout diagram 1122. The design procedure includes one or more of logic design, physical design or place and route. IC design layout diagram 1122 is presented in one or more data files having information of the geometrical patterns. For example, IC design layout diagram 1122 can be expressed in a GDSII file format or DFII file format.

Mask house 1130 includes data preparation 1132 and mask fabrication 1144. Mask house 1130 uses IC design layout diagram 1122 to manufacture one or more masks 1145 to be used for fabricating the various layers of IC device 1160 according to IC design layout diagram 1122. Mask house 1130 performs mask data preparation 1132, where IC design layout diagram 1122 is translated into a representative data file (RDF). Mask data preparation 1132 provides the RDF to mask fabrication 1144. Mask fabrication 1144 includes a mask writer. A mask writer converts the RDF to an image on a substrate, such as a mask (reticle) 1145 or a semiconductor wafer 1153. The design layout diagram 1122 is manipulated by mask data preparation 1132 to comply with particular characteristics of the mask writer and/or requirements of IC fab 1150. In FIG. 11, mask data preparation 1132 and mask fabrication 1144 are illustrated as separate elements. In some embodiments, mask data preparation 1132 and mask fabrication 1144 can be collectively referred to as mask data preparation.

In some embodiments, mask data preparation 1132 includes optical proximity correction (OPC) which uses lithography enhancement techniques to compensate for image errors, such as those that can arise from diffraction, interference, other process effects and the like. OPC adjusts IC design layout diagram 1122. In some embodiments, mask data preparation 1132 includes further resolution enhancement techniques (RET), such as off-axis illumination, sub-resolution assist features, phase-shifting masks, other suitable techniques, and the like or combinations thereof. In some embodiments, inverse lithography technology (ILT) is also used, which treats OPC as an inverse imaging problem.

In some embodiments, mask data preparation 1132 includes a mask rule checker (MRC) that checks the IC design layout diagram 1122 that has undergone processes in OPC with a set of mask creation rules which contain certain geometric and/or connectivity restrictions to ensure sufficient margins, to account for variability in semiconductor manufacturing processes, and the like. In some embodiments, the MRC modifies the IC design layout diagram 1122 to compensate for photolithographic implementation effects during mask fabrication 1144, which may undo part of the modifications performed by OPC in order to meet mask creation rules.

In some embodiments, mask data preparation 1132 includes lithography process checking (LPC) that simulates processing that will be implemented by IC fab 1150 to fabricate IC device 1160. LPC simulates this processing based on IC design layout diagram 1122 to create a simulated manufactured device, such as IC device 1160. The processing parameters in LPC simulation can include parameters associated with various processes of the IC manufacturing cycle, parameters associated with tools used for manufacturing the IC, and/or other aspects of the manufacturing process. LPC takes into account various factors, such as aerial image contrast, depth of focus (DOF), mask error enhancement factor (MEEF), other suitable factors, and the like or combinations thereof. In some embodiments, after a simulated manufactured device has been created by LPC, if the simulated device is not close enough in shape to satisfy design rules, OPC and/or MRC are be repeated to further refine IC design layout diagram 1122.

It should be understood that the above description of mask data preparation 1132 has been simplified for the purposes of clarity. In some embodiments, data preparation 1132 includes additional features such as a logic operation (LOP) to modify the IC design layout diagram 1122 according to manufacturing rules. Additionally, the processes applied to IC design layout diagram 1122 during data preparation 1132 may be executed in a variety of different orders.

After mask data preparation 1132 and during mask fabrication 1144, a mask 1145 or a group of masks 1145 are fabricated based on the modified IC design layout diagram 1122. In some embodiments, mask fabrication 1144 includes performing one or more lithographic exposures based on IC design layout diagram 1122. In some embodiments, an electron-beam (e-beam) or a mechanism of multiple e-beams is used to form a pattern on a mask (photomask or reticle) 1145 based on the modified IC design layout diagram 1122. Mask 1145 can be formed in various technologies. In some embodiments, mask 1145 is formed using binary technology. In some embodiments, a mask pattern includes opaque regions and transparent regions. A radiation beam, such as an ultraviolet (UV) beam, used to expose the image sensitive material layer (e.g., photoresist) which has been coated on a wafer, is blocked by the opaque region and transmits through the transparent regions. In one example, a binary mask version of mask 1145 includes a transparent substrate (e.g., fused quartz) and an opaque material (e.g., chromium) coated in the opaque regions of the binary mask. In another example, mask 1145 is formed using a phase shift technology. In a phase shift mask (PSM) version of mask 1145, various features in the pattern formed on the phase shift mask are configured to have proper phase difference to enhance the resolution and imaging quality. In various examples, the phase shift mask can be attenuated PSM or alternating PSM. The mask(s) generated by mask fabrication 1144 is used in a variety of processes. For example, such a mask(s) is used in an ion implantation process to form various doped regions in semiconductor wafer 1153, in an etching process to form various etching regions in semiconductor wafer 1153, and/or in other suitable processes.

IC fab 1150 is an IC fabrication business that includes one or more manufacturing facilities for the fabrication of a variety of different IC products. In some embodiments, IC fab 1150 is a semiconductor foundry. For example, there may be a manufacturing facility for the front end fabrication of a plurality of IC products (FEOL fabrication), while a second manufacturing facility may provide the back end fabrication for the interconnection and packaging of the IC products (BEOL fabrication), and a third manufacturing facility may provide other services for the foundry business.

IC fab 1150 includes fabrication tools 1152 configured to execute various manufacturing operations on semiconductor wafer 1153 such that IC device 1160 is fabricated in accordance with the mask(s), e.g., mask 1145. In various embodiments, fabrication tools 1152 include one or more of a wafer stepper, an ion implanter, a photoresist coater, a process chamber, e.g., a CVD chamber or LPCVD furnace, a CMP system, a plasma etch system, a wafer cleaning system, or other manufacturing equipment capable of performing one or more suitable manufacturing processes as discussed herein.

IC fab 1150 uses mask(s) 1145 fabricated by mask house 1130 to fabricate IC device 1160. Thus, IC fab 1150 at least indirectly uses IC design layout diagram 1122 to fabricate IC device 1160. In some embodiments, semiconductor wafer 1153 is fabricated by IC fab 1150 using mask(s) 1145 to form IC device 1160. In some embodiments, the IC fabrication includes performing one or more lithographic exposures based at least indirectly on IC design layout diagram 1122. Semiconductor wafer 1153 includes a silicon substrate or other proper substrate having material layers formed thereon. Semiconductor wafer 1153 further includes one or more of various doped regions, dielectric features, multilevel interconnects, and the like (formed at subsequent manufacturing steps).

In some aspects, a semiconductor device includes a substrate having a first side and a second side opposite the first side; a first set of electronic components at the first side of the substrate; and an isolation structure at the second side of the substrate, and overlapping the first set of electronic components based on a perspective along a vertical direction. The isolation structure includes an array of conductive strips. The isolation structure includes an array of conductive strips, and an open guard ring structure that extends along a periphery of the array of conductive strips and defines a space between two ends of the open guard ring structure. The semiconductor device further includes a passive component or a second set of electronic components at the second side of the substrate. Based on the passive component being at the second side of the substrate, the isolation structure is between the substrate and the passive component, and the passive component includes an inductor, a capacitor, or a power distribution network. Based on the second set of electronic components being at the second side of the substrate, the isolation structure is between the substrate and the second set of electronic components.

In some aspects, a method of manufacturing a semiconductor device includes forming a first set of electronic components at a first side of a substrate; and forming an isolation structure at a second side of the substrate, and overlapping the first set of electronic components based on a perspective along a vertical direction, the second side of the substrate opposite the first side of the substrate. The isolation structure includes an array of conductive strips, and an open guard ring structure that extends along a periphery of the array of conductive strips and defines a space between two ends of the open guard ring structure. The method further includes forming a passive component or a second set of electronic components at the second side of the substrate. Based on the passive component being at the second side of the substrate, the isolation structure is between the substrate and the passive component, and the passive component includes an inductor, a capacitor, or a power distribution network. Based on the second set of electronic components being at the second side of the substrate, the isolation structure is between the substrate and the second set of electronic components

In some aspects, a semiconductor device includes a substrate having a first side and a second side opposite the first side; a set of electronic components at the first side of the substrate; and one or more metallization layers at the second side of the substrate. The one or more metallization layers include an isolation structure and one or more conductive structures. The isolation structure includes an isolation structure that includes an array of conductive strips including a plurality of conductive strip groups separated by corresponding gaps, and an open guard ring structure that extends along a periphery of the array of conductive strips and defines a space between two ends of the open guard ring structure. The one or more conductive structures are configured as an inductor, a capacitor, or a power distribution network, the isolation structure being between the substrate and the one or more conductive structures.

The foregoing outlines features of several embodiments or examples so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments or examples introduced herein. Those skilled in the art should also realize that such equivalent constructions do not depart from the spirit and scope of the present disclosure and that they may make various changes, substitutions, and alterations herein without departing from the spirit and scope of the present disclosure.

1. A semiconductor device, comprising:
a substrate having a first side and a second side opposite the first side;
a first set of electronic components at the first side of the substrate;
an isolation structure at the second side of the substrate, and overlapping the first set of electronic components based on a perspective along a vertical direction, the isolation structure including:
an array of conductive strips, and
an open guard ring structure that extends along a periphery of the array of conductive strips and defines a space between two ends of the open guard ring structure; and
a passive component or a second set of electronic components at the second side of the substrate,
wherein
based on the passive component being at the second side of the substrate, the isolation structure is between the substrate and the passive component, and the passive component includes an inductor, a capacitor, or a power distribution network, and
based on the second set of electronic components being at the second side of the substrate, the isolation structure is between the substrate and the second set of electronic components.

2. The semiconductor device of claim 1, wherein
the periphery of the array of conductive strips is based on a polygon, including a square, a rectangle, a hexagon, or an octagon.

3. The semiconductor device of claim 1, wherein
the array of conductive strips includes a plurality of conductive strip groups separated by corresponding gaps.

4. The semiconductor device of claim 3, wherein
the plurality of conductive strip groups includes a first conductive strip group having corresponding conductive strips extending along a first direction and a second conductive strip group having corresponding conductive strips extending along a second direction different from the first direction.

5. The semiconductor device of claim 3, wherein
the plurality of conductive strip groups includes
a first conductive strip group having corresponding conductive strips extending along a first direction,
a second conductive strip group having corresponding conductive strips extending along a second direction,
a third conductive strip group having corresponding conductive strips extending along the first direction, and
a fourth conductive strip group having corresponding conductive strips extending along the second direction, and
the first direction is orthogonal to the second direction.

6. The semiconductor device of claim 1, wherein
the passive component is based on one or more conductive structures at the second side of the substrate.

7. The semiconductor device of claim 1, wherein the second set of electronic components is included in
a first semiconductor die that includes the first set of electronic components, the substrate, and the isolation structure, or
a second semiconductor die that is attached to the first semiconductor die.

8. The semiconductor device of claim 1, further comprising:
a notch filter or a band-stop filter electrically coupled to the isolation structure and configured to reduce a signal component within a band-stop band based on an operating frequency of the first set of electronic components.

9. The semiconductor device of claim 1, wherein
a width of each conductive strip of the array of conductive strips is less than 1/10 of a signal wavelength at an operating frequency of the first set of electronic components, and
a distance between adjacent conductive strips of the array of conductive strips is less than 1/10 of the signal wavelength at the operating frequency of the first set of electronic components.

10. The semiconductor device of claim 1, wherein
the isolation structure includes a conductive material including copper, aluminum, gold, or a combination thereof.

11. A method of manufacturing a semiconductor device, comprising:
forming a first set of electronic components at a first side of a substrate;
forming an isolation structure at a second side of the substrate, and overlapping the first set of electronic components based on a perspective along a vertical direction, the second side of the substrate opposite the first side of the substrate, the isolation structure including:
an array of conductive strips, and
an open guard ring structure that extends along a periphery of the array of conductive strips and defines a space between two ends of the open guard ring structure; and
forming a passive component or a second set of electronic components at the second side of the substrate,
wherein
based on the passive component being at the second side of the substrate, the isolation structure is between the substrate and the passive component, and the passive component includes an inductor, a capacitor, or a power distribution network, and
based on the second set of electronic components being at the second side of the substrate, the isolation structure is between the substrate and the second set of electronic components.

12. The method of claim 11, wherein
the forming the isolation structure comprises configuring the periphery of the array of conductive strips based on a polygon, including a square, a rectangle, a hexagon, or an octagon.

13. The method of claim 11, wherein
the forming the isolation structure comprises configuring the array of conductive strips as including a plurality of conductive strip groups separated by corresponding gaps.

14. The method of claim 13, wherein
the plurality of conductive strip groups includes
a first conductive strip group having corresponding conductive strips extending along a first direction,
a second conductive strip group having corresponding conductive strips extending along a second direction,
a third conductive strip group having corresponding conductive strips extending along the first direction, and
a fourth conductive strip group having corresponding conductive strips extending along the second direction, and
the first direction is orthogonal to the second direction.

15. The method of claim 11, wherein the forming the passive component at the second side of the substrate comprises:
disposing one or more conductive structures at the second side of the substrate, the isolation structure being between the substrate and the one or more conductive structures,
wherein the passive component is based on the one or more conductive structures.

16. The method of claim 11, wherein the forming the second set of electronic components at the second side of the substrate comprises:
including the second set of electronic components in a first semiconductor die that includes the first set of electronic components, the substrate, and the isolation structure, or
including the second set of electronic components in a second semiconductor die and attaching the second semiconductor die to the first semiconductor die.

17. The method of claim 11, wherein
the isolation structure includes a conductive material including copper, aluminum, gold, or a combination thereof.

18. A semiconductor device, comprising:
a substrate having a first side and a second side opposite the first side;
a set of electronic components at the first side of the substrate; and
one or more metallization layers at the second side of the substrate,
wherein the one or more metallization layers include:
an isolation structure that includes:
an array of conductive strips, and
an open guard ring structure that extends along a periphery of the array of conductive strips and defines a space between two ends of the open guard ring structure; and
one or more conductive structures configured as an inductor, a capacitor, or a power distribution network, the isolation structure being between the substrate and the one or more conductive structures.

19. The semiconductor device of claim 18, wherein
the periphery of the array of conductive strips is based on a polygon, including a square, a rectangle, a hexagon, or an octagon.

20. The semiconductor device of claim 18, wherein
the array of conductive strips includes a plurality of conductive strip groups separated by corresponding gaps,
the plurality of conductive strip groups includes
a first conductive strip group having corresponding conductive strips extending along a first direction,
a second conductive strip group having corresponding conductive strips extending along a second direction,
a third conductive strip group having corresponding conductive strips extending along the first direction, and
a fourth conductive strip group having corresponding conductive strips extending along the second direction, and
the first direction and the second direction are orthogonal to each other.
